(19) United States
(12) Patent Application Publication
(10) Pub. No.: US 2025/0245413 A1
(43) Pub. Date: Jul. 31, 2025

(54) TIMING-AWARE FILL

(71) Applicant: International Business Machines Corporation, Armonk, NY (US)

(72) Inventors: David WOLPERT, Poughkeepsie, NY (US); Matthew T. GUZOWSKI, Essex Junction, VT (US); Kerim KALAFALA, Rhinebeck, NY (US); Robert John ALLEN, Jericho, VT (US); Ronald Dennis ROSE, Essex Junction, VT (US); Alexander Joel SUESS, Hopewell Junction, NY (US); Michael Hemsley WOOD, Wilmington, DE (US); Margaret Annabelle ALLEN, Jericho, VT (US)

(21) Appl. No.: 18/422,319

(22) Filed: Jan. 25, 2024

(51) Int. Cl. G06F 30/398; G06F 30/392

(52) U.S. Cl. CPC G06F 30/398; G06F 30/392

(57) ABSTRACT

Embodiments of the present disclosure provide methods, systems, and computer program products for implementing intelligent timing aware metal fill optimization for an IC layout. The disclosed methods enable fill tooling to identify the existing metal tile density and provide timing-aware metal fill insertion to specifically target density requirements and enable effective timing characteristics of signal path nets.

### BACKGROUND

The present invention relates to integrated circuit design, and more specifically, to implementing metal density fill in an integrated circuit (i.e., IC or chip) design to achieve patterning density requirements and enable effective overall chip performance.

An IC or chip includes active devices or logic shapes forming electrical circuits, with metal wiring structures including active wire shapes connecting the active devices together. The active wire shapes form wiring metallization including multiple metal layers (e.g., 12 to 18 metal layers in a stack) in a back-end-of-line (BEOL) processing region of the chip, that form power and signal path nets connecting the different circuit logic together. Metal density fill includes metal fill shapes that are distinct from the main power and signal path design shapes, that are added to the wiring metallization of an IC design, (e.g., beyond active power and signal wiring shapes used for circuit logic) to satisfy metal density rules or patterning requirements for chip fabrication. A foundry often defines different density constraints, (e.g. minimum metal density and maximum metal density rules) at a cell level and global chip level to meet metal density requirements for its IC fabrication processes. Some existing systems run fill algorithms on each metal layer to ensure that a total metal density falls within a defined minimum density and maximum density range to meet patterning requirements. Metal fill density checks typically include a set of density checks (e.g., planar and vertical gradient density checks, multi-layer density checks, and bump density checks) and include considerations of tile location differences between cell-level and chip-level.

While the metal density rules provided by a foundry may avoid irregularities in a patterning process of the chip fabrication, unfortunately, added metal fill shapes can cause additional capacitance (e.g., planar capacitance and vertical capacitance) that affects the signal nets and logic shapes, resulting in performance issues for the chip. New techniques are needed for implementing metal density fill in an IC design layout that avoids excessive impact to power and signals and enables overall chip performance.

### SUMMARY

Embodiments of the present disclosure are directed to methods, systems, and computer program products for implementing timing aware metal fill optimization for an IC layout.

According to one embodiment of the present disclosure, a non-limiting computer implemented method is provided. The method comprises accessing physical design data for an integrated circuit (IC) layout, the physical design data comprising a netlist comprising active metal shapes of a metal shapes infrastructure forming signal path nets connecting different parts of the IC layout; performing timing-based design rule checking of the physical design data to identify timing characteristics of the signal path nets and net timing properties of the active metal shapes; and performing shape-based density design rule checking of the metal shapes infrastructure, based on the timing characteristics of the signal path nets and the net timing properties of the active metal shapes, to perform fill insertion of metal fill shapes to satisfy density requirements in the IC layout.

Other disclosed embodiments include a computer system and computer program product for implementing timing aware metal fill optimization for an IC layout, implementing features of the above-disclosed method.

### BRIEF DESCRIPTION OF THE DRAWINGS

FIG. 1 is a block diagram of an example computer environment for use in conjunction with one or more disclosed embodiments;

FIG. 2 is a block diagram of an example system for implementing intelligent timing aware metal fill optimization for an IC layout, according to one or more embodiments;

FIG. 3 is a flowchart illustrating example operations of a method for implementing intelligent timing aware metal fill optimization of one or more disclosed embodiments in an IC layout, according to one or more embodiments;

FIG. 4 is a flowchart illustrating example operations of a method for implementing intelligent timing aware fill optimization based on critical-first fill according to one or more embodiments;

FIG. 5 is a flowchart illustrating example operations of a method for implementing intelligent timing aware fill optimization based on non-critical-first fill according to one or more embodiments;

FIG. 6 is a flowchart illustrating example additional features and operations of a method for implementing intelligent timing aware fill optimization according to one or more embodiments; and

FIG. 7 is a flowchart illustrating a method for implementing intelligent timing aware fill optimization of a disclosed embodiment.

### DETAILED DESCRIPTION

Embodiments herein describe techniques for optimizing placement of metal fill shapes and optimizing metal fill density to achieve effective performance in an IC design using computer software tools. Novel techniques are disclosed for implementing timing aware fill optimization, limiting added metal fill shapes that most significantly impact signal timing characteristics, while maintaining sufficient metal fill shapes to meet minimum metal density requirements. The disclosed techniques enable IC designs to achieve global optimal timing characteristics for a given density pattern tile while limiting planar capacitance and vertical capacitance of a net associated with the density pattern tile from a specific metal fill shape. The disclosed techniques enable a fill optimization design tool to identify the existing metal tile density and provide timing-aware metal fill insertion to specifically target a minimum metal density threshold to satisfy density requirements of the IC design, and based on considerations of tile location differences between cell-level and chip-level, gradient density checks, multi-layer density checks, and bump density checks. The disclosed techniques enable optimal timing-aware metal fill insertion to non-critical signal path locations to achieve minimum density requirements, with automated processing to identify target active shapes for optimal metal fill insertion (e.g., adding, removing, or moving metal fill shapes) based on the signal impact of added metal fill shapes to the target active shapes. In addition, the proposed techniques may be used for adding metal fill shapes to minimize delay, and to intentionally add delay to signal paths that may otherwise arrive too quickly at their destination gates, i.e., to identify metal fill shapes insertion to minimize timing delay to signal paths, and to increase timing delay to signal paths.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

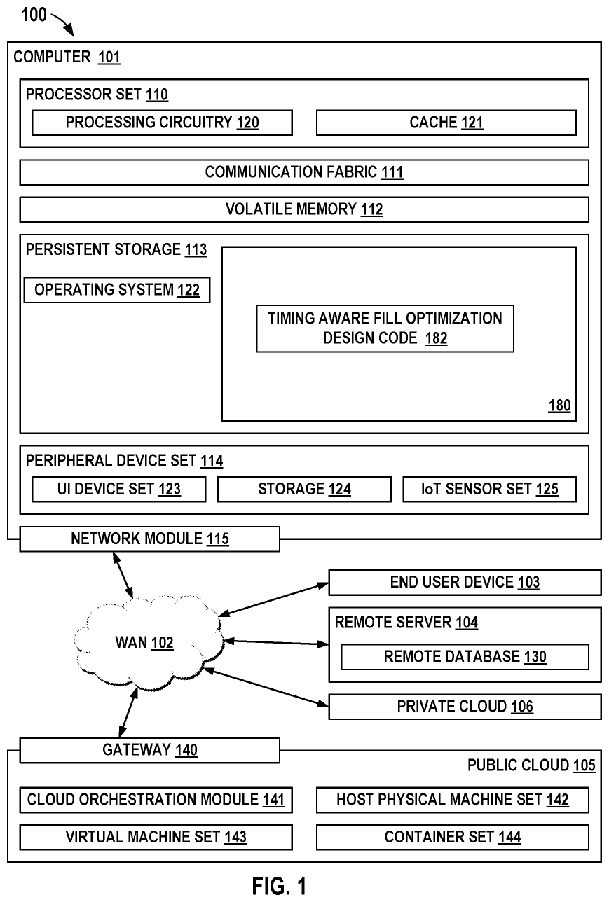

Referring to FIG. 1, a computing environment 100 contains an example of an environment for the execution of at least some of the computer code involved in performing the inventive methods, such as a Timing-Aware Fill Control Code 182, at block 180. In addition to block 180, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 180, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 180 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 180 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Embodiments of the present disclosure enable effective and efficient manufacture of integrated circuits by implementing intelligent metal density fill, identifying critical and non-critical signal paths of active metal shapes, and adding fill shapes to effectively limit added capacitance that impacts signal characteristics of the signal paths of active metal shapes, including planar capacitance and vertical capacitance resulting from the added metal fill shapes. Disclosed embodiments link timing knowledge with fill density requirements to implement intelligent timing aware fill optimization for an IC layout.

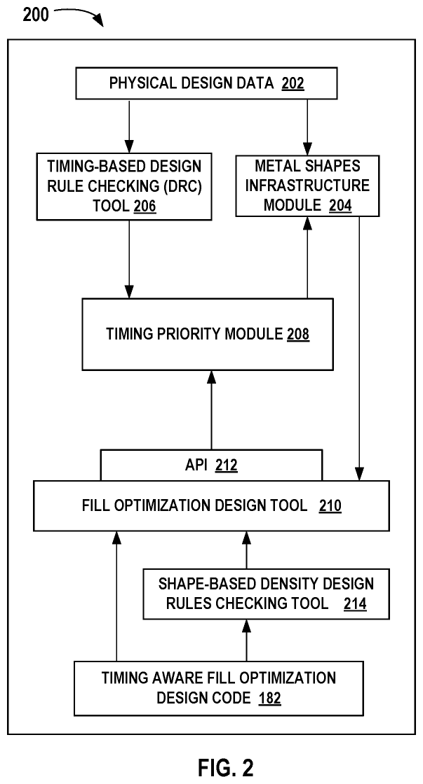

FIG. 2 illustrates an example system 200 for implementing intelligent timing aware fill optimization for an IC layout of disclosed embodiments. System 200 can be used in conjunction with the computer 101 and cloud environment of the computing environment 100 of FIG. 1 with the Timing-Aware Fill Optimization Design Control Code 182 for implementing methods according to one or more embodiments.

System 200 performs disclosed methods for optimally providing metal fill shapes based on determined cell and overall chip timing impacts of the added fill shapes. In an embodiment, metal fill shapes are added in available empty areas on the metal layers to satisfy minimum metal fill density requirements for the chip, using metal fill density rules provided by a foundry or fabrication facility, together with timing knowledge obtained for the chip. System 200 performs new techniques for adding metal fill shapes in an IC layout that significantly limit the timing impact of the added metal fill shapes on the chip (e.g., limits adding metal fill shapes impacting gate driven signals of critical active metal signal wires or nets) based on cell and overall chip timing results, while adding sufficient metal fill shapes with non-critical fill shapes to meet the fill density requirements. System 200 can optimally add metal fill shapes to achieve predefined minimum density requirements, while automating the process of identifying critical and non-critical path locations of active metal shapes for metal fill shapes placement based on net signal path timing characteristics, advantageously used for adding metal fill shapes.

System 200 includes physical design data 202 for a given IC layout used to implement fill optimization in accordance with disclosed embodiments. For example, system 200 obtains the physical design data 202 comprising a netlist representing different parts of the IC that are connected together in the IC layout, active metal shapes and their locations that connect the different parts in the IC layout, fill metal shapes, circuit shapes, active logic shapes, sub-circuits, cell and macro designs, and the like, which represent regions to be manufactured on different layers of the IC.

System 200 includes a metal shapes infrastructure module 204 comprising computer code, which identifies active metal shapes, and fill metal shapes of the physical design data 202 that form a chip metallization or metal shapes infrastructure comprising multiple metal layers of the IC layout. For example, the predefined active metal and fill metal shapes include rectangles or rectilinear polygons, (although other predefined shapes may be used) which represent active metal and fill wiring regions to be manufactured on different metal layers of the IC layout.

System 200 includes a timing-based Design Rule Checking (DRC) tool 206 comprising computer code, which inspects a netlist of the physical design data 202 for the IC layout and identifies net timing characteristics of signal path nets and net timing properties of the active metal shapes of the IC design, which form the signal path nets. The timing DRC tool 206 is used to ensure the net timing characteristics of signal path nets meet IC design manufacturing requirements and will not result in a chip failure. System 200 implements prioritization of fill metal shapes using a timing priority module 208 coupled to the timing DRC tool 206 of disclosed embodiments. The timing priority module 208 comprising computer code, which assigns priorities based on timing characteristics of the signal path nets and net timing properties of the active metal shapes obtained by the timing DRC tool 206, (e.g., using net timing properties or attributes of the active metal shapes) for each metal shape. System 200 provides the assigned priorities of fill metal shapes into the metal shapes infrastructure module 204 for the IC layout.

For example, net timing characteristics are provided into metal shapes infrastructure module 204 through properties based on each shape's net attributes (e.g., net name), where the timing priorities include timing slack values and/or timing fill priorities, e.g., represented by
[Timing_slack+100/ . . . /+1/0/−1/ . . . /−100] and/or
[Timing_fill_priority 1/2/ . . . /1,000,000,000]

For example, the timing property called timing slack generally represents how much extra time a given net has for a signal to propagate from a net source to a net sink. In one embodiment, for a net with a high timing slack value such as +100, a significant amount of metal fill shapes can be added around this net (e.g., without significantly impacting net timing characteristics). Alternatively, for a net with a low timing slack value such as +1, adding metal fill shapes should be avoided or limited away from this net because the added capacitance from the metal fill may impact net timing characteristics, and cause the net to have a negative timing slack value. Instead of using the timing slack, a predefined flat priority can be used, such as a priority of one, which indicates metal fill shapes should be kept away from this net If any other available fill space exists, i.e., open space a specified distance away from other signal nets exists, metal fill shapes can be placed in the open space so as not to affect the performance of other signal nets.

System 200 includes a fill optimization design tool 210 comprising computer code, which performs fill optimization techniques with the computer 101 and the Timing-Aware Fill Control Code 182 to implement methods of the present disclosure. System 200 includes an Application Program Interface (API) 212 for the fill optimization design tool 210 to poll timing results from the timing-based DRC tool 206 provided into the metal shapes infrastructure module 204 based on each shape's net timing properties or attributes and the net timing characteristics of the signal path nets. For example, the net timing characteristics of the signal path nets include timing signal slack or timing signal skew. System 200 includes a shape-based density DRC tool 214 comprising computer code, used by the fill optimization design tool 210 which verifies whether a specific density fill design (e.g., at a cell level or macro level) meets the metal density constraints imposed by the process technology or foundry to be used for the chip manufacturing. The fill optimization design tool 210, using the shape-based density DRC tool 214 together with timing results provided via the timing priority module 208, implements fill placement for timing aware metal fill optimization based on the shapes' net timing properties and the net timing characteristics of the signal path nets to ensure the IC design layout meets manufacturing metal density requirements and will not result in a chip failure.

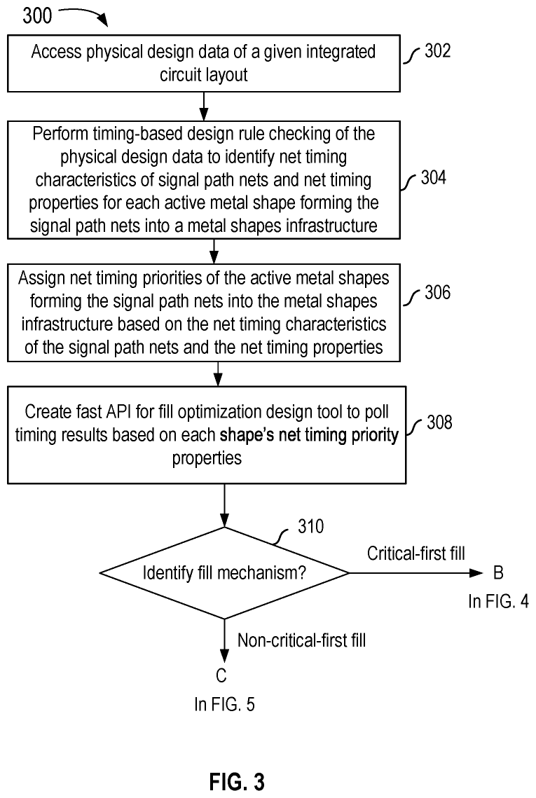

FIG. 3 is a flowchart of a method 300 for implementing intelligent timing aware fill optimization with timing aware metal shapes infrastructure in a given IC layout, according to one or more disclosed embodiments. For example, method 300 is implemented by system 200 including the Timing-Aware Fill Control Code 182 used with the computer 101 in accordance with one or more disclosed embodiments. In FIGS. 3, 4, 5, 6, and 7, the same reference numbers are used for identical or similar component as used in FIG. 2.

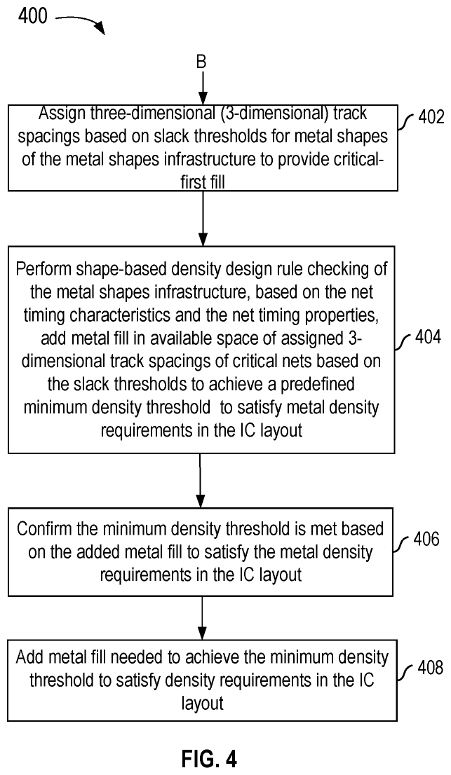

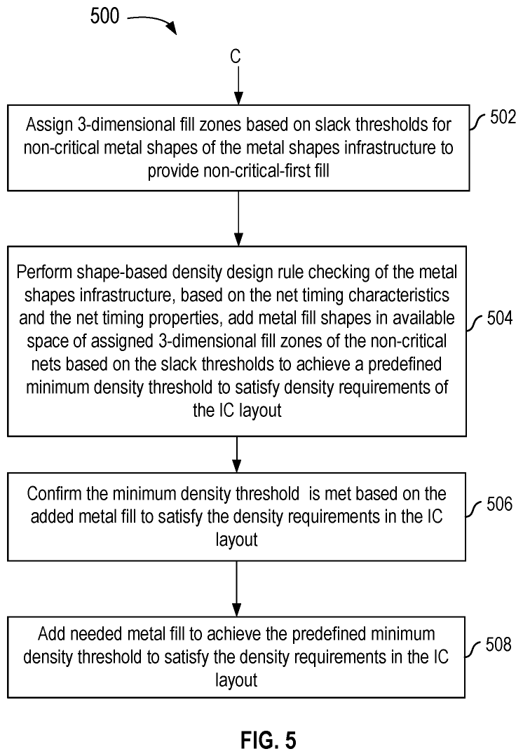

Operations of method 300 begin at block 302, system 200 accesses physical design data for an IC layout, such as physical design data 202 comprising a netlist representing the different parts (e.g., nets or nodes, wires or signal path nets shapes, logic) to be connected, and active metal shapes including their locations that implement signal path nets connecting different parts of the IC layout. At block 304, system 200 performs net timing-based design rules checking of the physical design data 202 to identify net timing characteristics of signal path nets and net timing properties of each of the active metal shapes of signal path nets of the metal shapes infrastructure. In an embodiment, system 200 sequentially processes tiles of the layers of the physical design data with the timing-based DRC tool 206 to identify timing results for signal paths and net timing attributes of each shape of the metal shapes infrastructure module 204. At block 306, system 200 assigns net timing priorities of the active metal shapes forming the signal path nets into the metal shapes infrastructure (e.g., timing priority module 208) to provide timing priority into each shape's property attributes of the metal shapes infrastructure module 204 from timing results of the timing-based DRC tool 206. At block 308, system 200 creates an API for the fill optimization design tool 210 to poll timing results based on each shape's net attributes via the timing priority module 208. At decision block 310, system 200 identifies a fill mechanism of a critical-first fill or a non-critical-first fill for implementing timing aware fill optimization for the IC layout. When a critical-first fill mechanism is identified, operations continue following entry point B in FIG. 4. Alternatively, when a non-critical-first fill mechanism is identified, operations continue following entry point C in FIG. 5.

FIG. 4 illustrates a method 400 (e.g., using the fill optimization design tool 210 with Timing-Aware Fill Control Code 182) for implementing intelligent timing aware fill optimization based on critical-first fill according to one or more embodiments.

Operations begin to add critical-first fill, where fill is added to critical signal path nets first at block 402, system 200 assigns 3-dimensional track spacings based on timing slack thresholds for the metal shapes (e.g., of the metal shapes infrastructure module 204) for the critical signal path nets, where the critical signal path nets are identified based on the timing characteristics of the signal path nets. In an embodiment, the 3-dimensional track spacings are created based on a 3-dimensional timing awareness of critical nets in the design, for example, with a keepout shape, based on timing slack thresholds starting with critical signal path nets struggling to meet timing characteristics. The assigned 3-dimensional track spacings address both planar capacitance and vertical capacitance (i.e., keeping away from the neighboring tracks, such as keeping one wire away on each side of a critical path signal net, and keeping away from wires above and below the critical path signal net). In an embodiment, each 3-dimensional track spacing defines a region around a critical path signal net based on respective timing slack thresholds, where adding metal fill is prevented or not allowed. For example, a-50 timing slack threshold means keep away from neighboring tracks and prohibit fill crossings on the layer above and the layer below the critical net struggling to meet timing characteristics. For example, a −5 slack may mean only keep away from neighboring tracks.

At block 404, system 200 performing shape-based design rule checking, adds metal fill in available space (e.g., white space) based on slack thresholds of the assigned 3-dimensional track spacings of critical signal path nets to achieve a predefined minimum density threshold to satisfy metal density requirements for the IC layout. Alternatively, at block 404 in a design layout where metal fill exists within the assigned 3-dimensional track spacings of critical nets, the system can remove metal fill from the 3-dimensional track spacing around critical signal path nets based on the assigned 3-dimensional track spacings of critical signal path nets. At block 406, system 200 confirms the minimum metal density threshold is met based on the added metal fill at block 404, to satisfy the density requirements for the IC layout. At block 408, system 200 optionally adds more metal fill needed to achieve the minimum density threshold of the metal density requirements for the IC.

FIG. 5 is a flowchart illustrating example operations of a method 500 (e.g., using the fill optimization design tool 210 with Timing-Aware Fill Control Code 182) for implementing intelligent timing aware fill optimization based on non-critical-first fill according to one or more embodiments.

At block 502, operations begin to add non-critical-first fill, where metal fill cells are added directly around non-critical signal paths first, system 200 assigns 3-dimensional fill zones based on timing slack thresholds of non-critical metal shapes of the metal shapes infrastructure module 204 to provide non-critical-first metal fill. In an embodiment, the 3-dimensional fill zones define a region around a non-critical signal path net based on respective timing slack thresholds, where metal fill is added. At block 504, system 200 performs shape-based design rule checking, checks for critical planar and vertical neighboring wires (signal path nets), and adds metal fill in the 3-dimensional fill zones based on the timing slack thresholds. System 200 adds planar metal fill adjacent the non-critical wire and/or adding vertical metal fill around the non-critical wire based on the timing slack threshold for the non-critical wire. For example, a +50 slack threshold can mean that as much vertical metal fill as possible should be added around that non-critical wire, but a +5 slack threshold means adding only planar fill. Alternatively, at block 504 in a design layout where metal fill exists within the assigned 3-dimensional zones of non-critical signal path nets, the system can remove vertical metal fill from the 3-dimensional fill zones above and below non-critical signal path nets based on critical vertical neighboring wires (signal path nets). At block 506, system 200 confirms metal density requirements for the IC are met based on the added metal fill at block 504. At block 508, system 200 adds more vertical metal fill, or prioritizes vertical metal fill for reinsertion that is needed to achieve the minimum density threshold to satisfy metal density requirements for the IC.

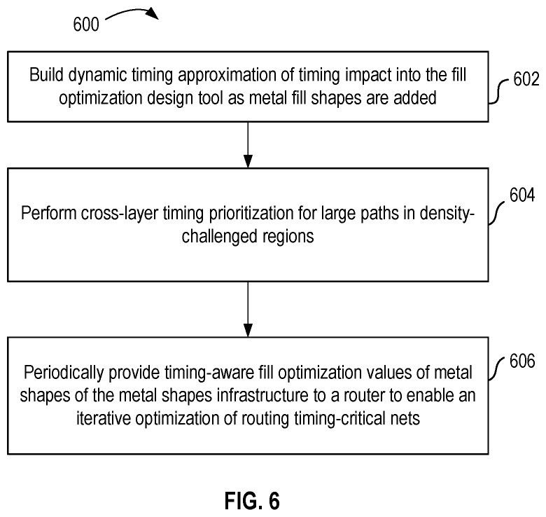

FIG. 6 is a flowchart illustrating example additional features and operations of a method 600 for implementing intelligent timing aware fill optimization according to one or more embodiments. Method 600 can be implemented by system 200 using the fill optimization design tool 210 with Timing-Aware Fill Control Code 182 and the computer 101 of FIG. 1 in accordance with one or more disclosed embodiments.

At block 602, system 200 builds a dynamic timing approximation of timing impact resulting for each metal fill shape added into the metal shapes infrastructure and the fill optimization design tool 210 as the metal fill shapes are added. In an embodiment, as shapes are added, system 200 maintains a running tally in the optimization design tool 210 of a potential timing impact resulting from each added metal fill shape. The cumulative net timing impact for the added metal fill shapes enables the optimization design tool 210 to ensure positive paths do not become negative and that weak negatives do not swap priorities with other paths in the metal shapes infrastructure module 204. In an embodiment, identifying the potential timing impact for each added metal fill shape is used for building a dynamic approximation of cumulative timing impact for the fill insertion of the metal fill shapes.

Building the dynamic approximation of cumulative timing impact directly into the optimization design tool 210 as metal fill shapes are added enables the optimization design tool 210 to dynamically determine adverse effects of the added metal fill shapes and implement some additional guard bands or guardrails to avoid further adverse results of the fill insertion process. For example, the dynamic approximation of cumulative timing impact enables the optimization design tool 210 to avoid a negative net timing characteristics impact of specific signal path nets, such as changing non-critical signal path nets to critical signal path nets.

At block 604, system 200 performs cross-layer timing prioritization for large paths in density-challenged regions, where some metal fill needs to be added to critical paths (e.g., implemented by deconstructing timing impacts per layer, or per macro or module, to create cross-layer timing priorities for fill insertion. For example, system 200 adds keep-outs to metal layer segments that are longer than a set length x before adding keep-outs to metal fill segments that are longer than a set length y, to balance impacts on timing for a given path versus per-layer density.

At block 606, system 200 periodically provides timing-aware fill optimization values or density map of metal shapes of the metal shapes infrastructure module 204 to a router to enable an iterative optimization of routing timing-critical nets in the IC layout. In an embodiment, system 200 provides the timing-aware fill optimization values to the router, which enables the router to optimize sparse routing for timing-critical nets to avoid coupling. In an embodiment, where such sparse wiring may result in system 200 adding more local fill insertion, which may result in a larger total capacitance in the design than would have resulted from pushing those wires slightly closer together and giving the fill tooling larger white space areas to overfill.

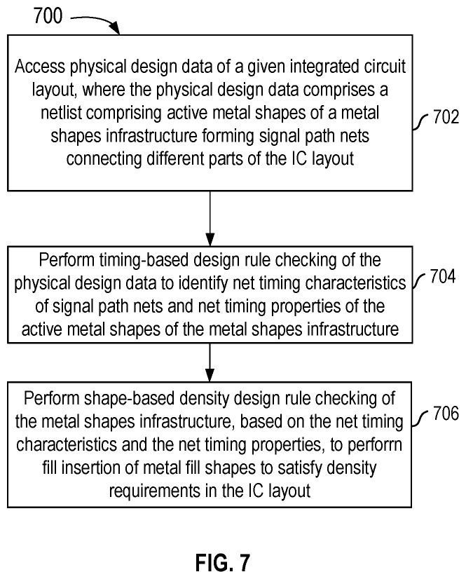

FIG. 7 is a flowchart illustrating a method for implementing intelligent timing aware fill optimization of a disclosed embodiment. Method 700 can be implemented by system 200 using the fill optimization design tool 210 with Timing-Aware Fill Control Code 182 and the computer 101 of FIG. 1 in accordance with one or more disclosed embodiments.

At block 702, system 200 accesses physical design data for an integrated circuit layout, the physical design data comprising a netlist comprising active metal shapes of a metal shapes infrastructure forming signal path nets connecting different parts of the IC layout. The physical design data also includes fill metal shapes, circuit shapes or active logic shapes, sub-circuits, cell and macro designs, and the like, which represent regions to be manufactured on different layers of the IC.

At block 704, system 200 performs timing-based design rule checking of the physical design data to identify net timing characteristics of signal path nets and net timing properties of the active metal shapes of the metal shapes infrastructure of the IC design. In one embodiment, the timing-based DRC tool 206 comprising computer code, inspects the netlist of the physical design data 202 for the IC layout and identifies timing characteristics of signal path nets of the IC design, where the signal path nets comprise the active metal shapes of a metal shapes infrastructure connecting the different parts of the IC layout. The physical design data includes metal fill shapes of the metal shapes infrastructure, and both timing-based design rule checking and shape-based density design rule checking of the metal shapes infrastructure include checking the metal fill shapes. In an embodiment, performing the timing-based design rule checking of the physical design data enables optimizing the insertion of metal fill shapes based on the impact to the net timing characteristics of the signal path nets. The net timing characteristics are determined by a combination of resistance and capacitance values of the signal path nets (e.g., where a timing-based design rule checking tool performs resistance capacitance (RC) analysis to determine the net timing characteristics or time delay of the signal path nets). Increased capacitance resulting from fill insertion combined with the signal path net resistance can result in a timing penalty or time delay that adversely changes the net timing characteristics of one or more specific signal path nets. For example, such increased capacitance from metal fill insertion that degrades the net timing characteristics (i.e., increasing time delay of one or more signal path nets) can result from the position of an added metal fill shape relative to the active wiring shape of the signal path net with the metal fill shapes size and number of the metal fill shapes. The resistance of metal fill shapes is inversely proportional to a wire width (e.g., smaller wire size has higher resistance), and directly proportional to a wire length of a given signal path net. In an embodiment, the net timing properties of the active metal shapes comprise one or more selected net timing properties, such as a timing slack property or timing slack threshold of the respective critical signal path nets formed by the active metal shapes. The timing slack property generally represents how much extra time a given signal path net has for a signal to propagate from a net source to a net sink. In one embodiment, for a signal path net with a high timing slack value such as +100, a significant amount of metal fill shapes can be added around the active wiring shape of the signal path net. Alternatively, for a signal path net with a low timing slack value such as +1, adding metal fill shapes should be avoided or limited away from the active wiring shape of the signal path net because the added capacitance may cause a significant time delay impact degrading the timing characteristics of the signal path net.

At block 706, system 200 performs shape-based design rule checking, based on the net timing characteristics of the signal path nets and the net timing properties of the active metal shapes, to perform fill insertion of metal fill shapes to satisfy density requirement in the IC layout. In an embodiment, the shape-based design rule checking includes cell level shape-based density design rule checking and chip level shape-based density design rule checking to satisfy density requirements of the IC layout. In an embodiment, the shape-based design rule checking identifies a predefined minimum density threshold to satisfy metal density requirements in the IC layout, and that advantageously avoids excessive impact to power and signals and enables overall effective chip performance. In an embodiment, the shape-based density design rule checking includes identifying a potential timing impact for each added metal fill shape to build a dynamic approximation of timing impact for the fill insertion of the metal fill shapes.

While the foregoing is directed to embodiments of the present invention, other and further embodiments of the invention may be devised without departing from the basic scope thereof, and the scope thereof is determined by the claims that follow.

What is claimed is:

1. A method comprising:
accessing physical design data for an integrated circuit (IC) layout, wherein the physical design data comprises a netlist comprising active metal shapes of a metal shapes infrastructure forming signal path nets connecting different parts of the IC layout;
performing timing-based design rule checking of the physical design data to identify net timing characteristics of the signal path nets and net timing properties of the active metal shapes of the metal shapes infrastructure; and
performing shape-based density design rule checking of the metal shapes infrastructure, based on the net timing characteristics and the net timing properties of the active metal shapes, to perform fill insertion of metal fill shapes to satisfy density requirements in the IC layout.

2. The method of claim 1, wherein the physical design data further comprises metal fill shapes of the metal shapes infrastructure, and wherein performing timing-based design rule checking of the physical design data further comprises performing timing-based design rule checking of the active metal shapes forming the signal path nets and the metal fill shapes of the metal shapes infrastructure to identify the net timing characteristics of the signal path nets and the net timing properties of the active metal shapes of the metal shapes infrastructure, and to identify metal fill shapes insertion to minimize timing delay to signal paths, and to increase timing delay to signal paths.

3. The method of claim 1, wherein performing shape-based density design rule checking of the metal shapes infrastructure further comprises assigning net timing priorities of the active metal shapes forming the signal path nets into the metal shapes infrastructure based on the net timing characteristics of the signal path nets and the net timing properties of the active metal shapes.

4. The method of claim 1, wherein the physical design data further comprises metal fill shapes of the metal shapes infrastructure, and wherein performing shape-based density design rule checking of the metal shapes infrastructure includes performing shape-based density design rule checking of the active metal shapes forming the signal path nets and the metal fill shapes.

5. The method of claim 1, wherein performing shape-based density design rule checking of the metal shapes infrastructure further comprises performing the fill insertion of metal fill shapes to achieve a predefined minimum density threshold to satisfy density requirements in the IC layout.

6. The method of claim 1, wherein performing shape-based density design rule checking of the metal shapes infrastructure further comprises identifying critical signal path nets based on the net timing characteristics of the signal path nets, and performing shape-based density design rule checking of the critical signal path nets first.

7. The method of claim 6, wherein performing shape-based density design rule checking of the critical signal path nets first further comprises assigning 3-dimensional track spacings based on timing slack thresholds of the critical signal path nets, and performing the fill insertion of metal fill shapes based on the timing slack thresholds of respective critical signal path nets to achieve a predefined minimum density threshold to satisfy density requirements in the IC layout.

8. The method of claim 1, wherein performing shape-based density design rule checking of the metal shapes infrastructure further comprises identifying non-critical signal path nets based on the net timing characteristics of the signal path nets, and performing shape-based density design rule checking of the non-critical signal path nets first.

9. The method of claim 8, wherein performing shape-based density design rule checking of the non-critical signal path nets first further comprises assigning 3-dimensional fill zones based on timing slack thresholds of the non-critical signal path nets, and adding metal fill shapes in the 3-dimensional fill zones based on the timing slack thresholds of respective non-critical signal path nets to achieve a predefined minimum density threshold to satisfy density requirements in the IC layout.

10. The method of claim 1, wherein performing shape-based density design rule checking of the physical design data further comprises identifying a potential timing impact for each added metal fill shape to build a dynamic approximation of timing impact for the fill insertion of the metal fill shapes.

11. A system, comprising one or more computer processors; and a memory containing a program which when executed by the one or more computer processors performs an operation, the operation comprising:
accessing physical design data for an integrated circuit (IC) layout, the physical design data comprising a netlist comprising active metal shapes of a metal shapes infrastructure forming signal path nets connecting different parts of the IC layout;
performing timing-based design rule checking of the physical design data to identify net timing characteristics of the signal path nets and net timing properties of the active metal shapes of the metal shapes infrastructure; and
performing shape-based density design rule checking of the metal shapes infrastructure, based on the net timing characteristics and the net timing properties of the active metal shapes, to perform fill insertion of metal fill shapes to satisfy density requirements in the IC layout.

12. The system of claim 11, wherein performing shape-based density design rule checking of the metal shapes infrastructure further comprises assigning net timing priorities of the active metal shapes forming the signal path nets into the metal shapes infrastructure based on the net timing characteristics of the signal path nets and the net timing properties.

13. The system of claim 11, wherein performing shape-based density design rule checking of the metal shapes infrastructure further comprises identifying critical signal path nets based on the net timing characteristics of the signal path nets, and performing shape-based density design rule checking of the critical signal path nets first.

14. The system of claim 13, wherein performing shape-based density design rule checking of the critical signal path nets first further comprises assigning 3-dimensional track spacings based on timing slack thresholds of the critical signal path nets, and performing the fill insertion of metal fill shapes based on the timing slack thresholds of respective critical signal path nets to achieve a predefined minimum density threshold to satisfy density requirements in the IC layout.

15. The system of claim 11, wherein performing shape-based density design rule checking of the metal shapes infrastructure further comprises identifying non-critical signal path nets based on the net timing characteristics of the signal path nets, and performing shape-based density design rule checking of the non-critical signal path nets first.

16. A computer program product comprising a computer-readable storage medium having computer-readable program code embodied therewith, the computer-readable program code executable by one or more computer processors to perform an operation comprising:
accessing physical design data for an integrated circuit (IC) layout, the physical design data comprising a netlist comprising active metal shapes of a metal shapes infrastructure forming signal path nets connecting different parts of the IC layout;
performing timing-based design rule checking of the physical design data to identify net timing characteristics of the signal path nets and net timing properties of the active metal shapes of the metal shapes infrastructure; and
performing shape-based density design rule checking of the metal shapes infrastructure, based on the net timing characteristics and the net timing properties of the active metal shapes, to perform fill insertion of metal fill shapes to satisfy density requirements in the IC layout.

17. The computer program product of claim 16, wherein performing shape-based density design rule checking of the metal shapes infrastructure further comprises assigning net timing priorities of the active metal shapes forming the signal path nets into the metal shapes infrastructure based on the net timing characteristics of the signal path nets and the net timing properties.

18. The computer program product of claim 16, wherein performing shape-based density design rule checking of the metal shapes infrastructure further comprises identifying critical signal path nets based on the net timing characteristics of the signal path nets, and performing shape-based density design rule checking of the critical signal path nets first.

19. The computer program product of claim 18, wherein performing shape-based density design rule checking of the critical signal path nets first further comprises assigning 3-dimensional track spacings based on timing slack thresholds of the critical signal path nets, and performing g the fill insertion of metal fill shapes based on the timing slack thresholds of respective critical signal path nets to achieve a predefined minimum density threshold to satisfy density requirements in the IC layout.

20. The computer program product of claim 16, wherein performing shape-based density design rule checking of the metal shapes infrastructure further comprises identifying non-critical signal path nets based on the net timing characteristics of the signal path nets, and performing shape-based density design rule checking of the non-critical signal path nets first.
